(19) United States
(12) Patent Application Publication
(10) Pub. No.: US 2025/0240924 A1
(43) Pub. Date: Jul. 24, 2025

(54) REFRIGERANT STORAGE DEVICE FOR MAGNETIC FIELD MEASUREMENT APPARATUS

(71) Applicant: KOREA RESEARCH INSTITUTE OF STANDARDS AND SCIENCE, Daejeon (KR)

(72) Inventors: Kwon-Kyu YU, Daejeon (KR); Yong-Ho LEE, Daejeon (KR); Jin-Mok KIM, Daejeon (KR); Bo-Kyung KIM, Daejeon (KR)

(21) Appl. No.: 19/172,659

(22) Filed: Apr. 8, 2025

Related U.S. Application Data
(63) Continuation of application No. PCT/KR2023/017934, filed on Nov. 9, 2023.

(30) Foreign Application Priority Data
Nov. 15, 2022 (KR) 10-2022-0152263

(51) Int. Cl. H05K 7/20; G01R 33/00; G01R 33/035

(52) U.S. Cl. CPC H05K 7/20327; G01R 33/007; H05K 7/20318; H05K 7/20372; H05K 7/20381; G01R 33/0354

(57) ABSTRACT

A refrigerant storage device for a magnetic field measurement apparatus according to an example embodiment of the present disclosure includes: an outer container; and an inner container inserted into the outer container and storing a liquid refrigerant. The inner container may include: a neck portion into which a baffle insert is inserted; and a body portion having a diameter increased compared to the neck portion. The neck portion may include: a plurality of cylindrical neck portions aligned vertically with each other; and at least one thermal anchor inserted between cylindrical neck portions adjacent to each other. The thermal anchor may be in direct contact with refrigerant vaporization gas. Each of the cylindrical neck portions may have a double-wall structure including an inner cylindrical portion and an outer cylindrical portion. The thermal anchor may include: a cylindrical anchor portion disposed between the inner cylindrical portion and the outer cylindrical portion; an outer washer portion coupled to an external side surface of the cylindrical anchor portion; and an inner washer portion coupled to an internal side surface of the cylindrical anchor portion.

### CROSS-REFERENCE TO RELATED APPLICATIONS

This application is a continuation of and claims priority to PCT/KR2023/017934 filed on Nov. 9, 2023, which claims priority to Korea Patent Application No. 10-2022-0152263 filed on Nov. 15, 2022, the entireties of which are both hereby incorporated by reference.

### TECHNICAL FIELD

The present disclosure relates to a magnetic field measurement apparatus and a refrigerant storage container for the magnetic field measurement apparatus, and more particularly to, a refrigerant storage container for a magnetic field measurement apparatus including a coil-in-vacuum.

### BACKGROUND ART

Magnetocardiography (MCG), a technique for measuring a magnetic field signal generated from ionic current activity of the heart muscle, may be useful for diagnosis of heart disease.

A superconducting quantum interference device (SQUID) is an ultra-sensitive sensor, capable of measuring ultra-low magnetic fields generated in biological activities of heart, brain, nerves and the like. A SQUID sensor operates at low temperature of 4 K or 77 K. Measurement sensitivity is several to tens of fT/√Hz. In general, liquid nitrogen or liquid helium is used to cool the SQUID sensor to a low temperature. A low-temperature refrigerant storage container, capable of storing such a low-temperature refrigerant, is required. The low-temperature refrigerant storage container has a dual structure including a helium internal storage container (a helium tank) storing the low-temperature refrigerant and an external cylinder (a vacuum tank) at room temperature, and a vacuum state is maintained therebetween.

To measure a high-sensitivity signal, it is advantageous to use a SQUID including a low-temperature superconductor. Since niobium (Nb), a superconducting material for use in a low-temperature superconducting SQUID, has a critical temperature of about 9 K, cooling using liquid helium or a low-temperature refrigerator is required. A structure, a thickness, and a mounting method of a thermal insulating material need to be optimized so as to reduce thermal magnetic noise, caused by metal insulation materials (supperinsulation and thermal shield) mounted in a vacuum unit of a Dewar, while reducing an evaporation rate of the Dewar. In addition, since a helium gas is likely to permeate through a small gap, high density of glass fiber reinforced plastic used as a Dewar material is required.

Since the intensity of a magnetic signal is decreased in inverse proportion to the square of a distance from a magnetic field signal source, a distance between the signal source and a pick-up coil needs to be significantly reduced so as to improve a signal-to-noise ratio (SNR). Research into such a method has been conducted to develop and use a coil-in-vacuum (CIV) SQUID in which a pick-up coil is disposed outside a helium tank, for example, a vacuum unit.

In the case of a CIV SQUID, a pick-up coil and a SQUID sensor are disposed to be maintained in a vacuum state. Accordingly, only a low-temperature refrigerant is present in an internal helium storage container storing a liquefied refrigerant. Accordingly, a neck portion of the internal helium storage container has only to be provided with a path, capable of filling a refrigerant. Accordingly, a diameter of the neck portion may be significantly decreased. As a result, heat flowing through the neck portion may be reduced to decrease an evaporation rate of the liquefied refrigerant.

As heat enters the internal helium storage container, liquid helium is vaporized while boiling. In this case, vibration occurs due to boiling of a liquid in the internal helium storage container. When a pick-up coil is mounted on an external vacuum surface rather than in the internal helium storage container, a vibration effect caused by boiling of the liquid helium may be reduced.

In addition, when a pick-up coil and a SQUID are mounted in vacuum, a cooling rate at the time of initial cooling is reduced as compared with a cooling rate when directly immersed in liquid helium, thereby alleviating rapid contraction stress generated during cooling and removing physical and chemical damages occurring when air or the like, flowing into the internal helium storage container, is adsorbed and condensed to a surface of the SQUID.

The inventor of the present invention has invented a Korean Patent Publication No. 10-2022-0080390 A of a double-wall structure. Thermal anchors were inserted between inner cylinders of a divided double-wall structure, and were screwed to inner sidewall of the inner cylinder. However, such a structure may cause leakage of refrigerant gas due to a difference in thermal expansion coefficients depending on temperature. Accordingly, a structure of a double-wall and a thermal anchor having a more stable structure is required.

### DISCLOSURE OF THE INVENTION

### Technical Problem

An aspect of the present disclosure is to provide a structure and a shape of a Dewar for regulating an evaporation rate (or pressure) of a storage container storing a low-temperature refrigerant and improving cooling characteristics of a magnetic field measurement apparatus.

An aspect of the present disclosure is to provide a structure and a shape of a low-temperature refrigerant storage container for improving stability of a refrigerant-lossless magnetic field measurement apparatus.

An aspect of the present disclosure is to provide a cooling apparatus having a neck portion structure of a double-wall structure, capable of blocking radiant heat.

An aspect of the present disclosure is to provide a magnetic field measurement apparatus having a vaporized refrigerant collection tube (a He gas return tube) of a coaxial double-tube structure.

An aspect of the present disclosure is to provide a cooling apparatus, capable of recycling a refrigerant.

### Technical Solution

A refrigerant storage device for a magnetic field measurement apparatus according to an example embodiment includes: an outer container; and an inner container inserted into the outer container and storing a liquid refrigerant. The inner container may include: a neck portion into which a baffle insert is inserted; and a body portion having a diameter increased compared to the neck portion. The neck portion may include: a plurality of cylindrical neck portions aligned vertically with each other; and at least one thermal anchor inserted between cylindrical neck portions adjacent to each other. The thermal anchor may be in direct contact with refrigerant vaporization gas. Each of the cylindrical neck portions may have a double-wall structure including an inner cylindrical portion and an outer cylindrical portion. The thermal anchor may include: a cylindrical anchor portion disposed between the inner cylindrical portion and the outer cylindrical portion; an outer washer portion coupled to an external side surface of the cylindrical anchor portion; and an inner washer portion coupled to an internal side surface of the cylindrical anchor portion.

In an example embodiment, the inner washer portion may include a plurality of refrigerant through-holes arranged in an azimuth direction, and the refrigerant vaporization gas may move through the refrigerant through-holes.

In an example embodiment, the refrigerant storage device may further include a temperature control rod coupled to the refrigerant through-hole to extend in a direction in which the inner container extends.

In an example embodiment, one end of the inner cylindrical portion may include a first recessed portion recessed on an external side surface, and the cylindrical anchor portion may be coupled to the first recessed portion.

In an example embodiment, a reinforcement portion may include a cylindrical reinforcement portion and a washer-shaped reinforcement flange portion coupled to an external side of one end of the cylindrical reinforcement portion. One end of the outer cylindrical portion may include a second recessed portion recessed on an internal side surface, and the cylindrical reinforcement portion may be inserted into and coupled to the second recessed portion of the outer cylindrical portion.

In an example embodiment, the outer washer portion may further include a first step portion coupled to the reinforcement flange portion.

In an example embodiment, the inner washer portion may further include a second step portion coupled to the inner cylindrical portion.

In an example embodiment, an inner diameter of the inner cylindrical portion is constant, an outer diameter of the inner cylindrical portion may be larger on opposite ends of the inner cylindrical portion, an inner diameter of the outer cylindrical portion may be constant, and an outer diameter of the outer cylindrical portion may be larger on opposite ends of the outer cylindrical portion.

In an example embodiment, the refrigerant storage device may further include: refrigerant exhaust tube disposed at the baffle insert and exhausting vaporized refrigerant gas; a refrigerant injection tube disposed at the baffle insert and injecting a refrigerant; and a recondenser connected to the refrigerant exhaust tube and the refrigerant injection tube and condensing a vaporized refrigerant exhausted through the refrigerant injection tube. The refrigerant exhaust tube and the refrigerant injection tube may have a coaxial structure.

In an example embodiment, the refrigerant injection tube may have a double-tube structure including an inner tube and an outer tube.

A refrigerant storage device for a magnetic field measurement apparatus according to an example embodiment includes: an outer container; and an inner container inserted into the outer container and storing a liquid refrigerant. The inner container may include: a neck portion into which a baffle insert is inserted; and a body portion having a diameter increased compared to the neck portion. The neck portion may include: a plurality of cylindrical neck portions aligned vertically with each other; and at least one thermal anchor inserted between cylindrical neck portions adjacent to each other. The thermal anchor may be in direct contact with a refrigerant vaporization gas, and a temperature control rod may be coupled to the thermal anchor to extend within the inner container in a direction in which the inner container extends.

In an example embodiment, each of the cylindrical neck portions may have a double-wall structure including an inner cylindrical portion and an outer cylindrical portion. The thermal anchor may include: a cylindrical anchor portion disposed between the inner cylindrical portion and the outer cylindrical portion; an outer washer portion coupled to an external side surface of the cylindrical anchor portion; and an inner washer portion coupled to an internal side surface of the cylindrical anchor portion.

In an example embodiment, the inner washer portion may include a plurality of refrigerant through-holes arranged in an azimuth direction, and the refrigerant vaporization gas may move through the refrigerant through-holes.

In an example embodiment, the temperature control rod may be coupled to the refrigerant through-hole.

### Advantageous Effects

As set forth above, a refrigerant storage device for a magnetic field measurement apparatus according to an example embodiment may inhibit refrigerant leakage caused by a difference in coefficients of thermal expansion in a refrigerant storage container, improve cooling characteristics to decrease the number of thermal anchors, and improve mechanical stability.

A refrigerant storage device for a magnetic field measurement apparatus according to an example embodiment may provide stable operating characteristics by inserting a temperature control rod to control an evaporation rate.

### BRIEF DESCRIPTION OF THE DRAWINGS

FIGS. 1 and 2 are conceptual diagrams illustrating a magnetic field measurement apparatus according to an example embodiment of the present disclosure.

FIG. 3 is a cross-sectional view illustrating a neck portion and a thermal anchor of an inner container of the magnetic field measurement apparatus of FIG. 1.

FIG. 4 is an enlarged view of a coupling portion of the thermal anchor and the neck portion of FIG. 3.

FIG. 5 is a perspective view illustrating the thermal anchor and a reinforcement plate of the magnetic field measurement apparatus of FIG. 1.

FIG. 6 is a plan view when viewing a lower surface of the inner container in the magnetic field measurement apparatus of FIG. 1.

FIG. 7A is a top view of a SQUID sensor module mounting plate of the magnetic field measurement apparatus of FIG. 1.

FIG. 7B is a bottom view of the SQUID sensor module mounting plate of the magnetic field measurement apparatus of FIG. 1.

FIG. 8 is a cross-sectional view taken along line A-A′ of FIG. 7A.

FIG. 9 is a cross-sectional view taken along line B-B′ of FIG. 7A.

FIG. 10 is a cross-sectional view taken along line C-C′ of FIG. 7A.

FIG. 11 is a perspective view illustrating an auxiliary thermal anchor of FIG. 1.

### MODE FOR CARRYING OUT THE INVENTION

A conventional refrigerant storage container (a cooling device or a Dewar) for biomagnetic measurement is non-electroconductive and is manufactured using glass fiber reinforced plastic (GFRP), a non-magnetic material. A CIV-type SQUID device maintains a vacuum between an inner container and an outer container, and the SQUID sensor is disposed in the vacuum. The inner container may have a neck portion and a body portion having a larger diameter than the neck portion, and may store a refrigerant.

A refrigerant storage device may block heat introduction from the outside to reduce an evaporation rate of expensive refrigerants (liquid helium and/or liquid nitrogen). A vacuum layer may be formed between an inner container and an outer container to block introduction of convective heat. A superinsulator may be installed between the inner container and the outer container to block introduction of radiant heat. A plurality of thermal anchors and a thermal shield connected to the thermal anchor are disposed to surround the inner container. The thermal anchor and the thermal shield connected to the thermal anchor may form a thermal gradient, and may block the introduction of radiant heat. A material having low thermal conductivity, such as glass fiber reinforced plastic (GFRP), may be used in the inner and outer containers to block convective heat.

A thermal anchor and a thermal shield are provided to perform cooling by recycling waste heat exhausted to the outside by natural evaporation of a refrigerant. Conventionally, the thermal anchor is attached to an external side of a washer-shaped neck portion having a thickness of several millimeters (for example, 4 mm). The thermal shield is connected to a washer-shaped external surface of the thermal anchor and has a cylindrical structure extending to surround the inner container.

Glass fiber reinforced plastic (GFRP), used as a material of the inner container, has significantly low thermal conductivity (0.1 W/m.K @20K). When the thermal anchor is attached to an external side of the neck portion having several millimeters (for example, 4 mm), temperature of the thermal anchor may experimentally increase to about 40K when liquid helium is used as a refrigerant. Therefore, the thermal anchor has a limitation in cooling capacity. In addition, when a conventional thermal anchor is used, recycling efficiency of waste heat is significantly reduced. Accordingly, there is a need to improve waste heat recycling efficiency.

A conventional refrigerant storage device has high thermal resistance. Due to an inner container having high thermal resistance, temperature of a thermal anchor disposed outside the inner container fails to rapidly respond to changes in storage level of a refrigerant, evaporation amount of the refrigerant, pressure of the inner container, and amount of heat introduced from the outside. Accordingly, a structure is required that allows the temperature of the thermal anchor and thermal shield to rapidly respond to a change in the amount of heat introduced from the outside, or the like, and to rapidly cool down.

When the amount of heat introduced from the outside increases, the temperature of the thermal anchor and thermal shield may increase. In this case, cooling temperature of a magnetic sensor increases in a magnetic field measurement system with the magnetic sensor disposed in a vacuum. Accordingly, the overall operational stability of the magnetic field measurement system may be significantly reduced to result in an unstable operation.

The refrigerant storage device according to an example embodiment may address an issue such as a cooling limitation of the thermal anchor caused by the high thermal resistance of the internal container. For example, the thermal anchor may be in direct contact with cold refrigerant vaporization gas inside the inner container. Accordingly, the thermal anchor may be cooled to a temperature, similar to refrigerant waste heat temperature (for example, 20K).

In the refrigerant storage device according to an example embodiment, a thermal anchor may be coupled to and fitted into the neck portion of the divided inner container, and the thermal anchor may be in direct contact with refrigerant vaporization gas. Accordingly, the thermal anchor may be cooled to a temperature, similar to a temperature of the refrigerant vaporization gas or the refrigerant waste heat temperature (for example, 20K), resulting in improved recycling efficiency of the waste heat. In addition, the temperatures of the thermal anchor and thermal shield may be maintained to be constant by improving cooling efficiency, and the internal container may stably store a liquid refrigerant.

The refrigerant storage device according to an example embodiment may maintain the temperatures of the thermal anchor and the thermal shield to be constant in spite of a change in the amount of heat introduced from the outside, and thus the amount of change in temperature of a magnetic sensor may be reduced to significantly improve operational stability of the system.

The refrigerant storage device according to an example embodiment may use a material such as GFRP to reduce conduction heat, and may use a CIV manner to block introduction of convective heat.

A thermal strain coefficient (or a coefficient of thermal expansion) of a metallic thermal anchor and a non-metallic GFRP are different from each other. A thermal anchor is inserted into and coupled to a neck portion of the inner container. For example, when a thermal anchor is inserted between an upper neck container and a lower neck container, cold leak may occur due to a difference in thermal expansion coefficients. When the refrigerant vaporization gas leaks from the inner container, the degree of vacuum in a space between the inner container and the outer container may decrease and a thermal insulation effect may deteriorate. Therefore, the neck portion of the inner container, into which the thermal anchor is inserted, may have a double-wall structure of an inner cylindrical portion and an outer cylindrical portion to inhibit cold leak. The thermal anchor may be inserted between the inner cylindrical portion and the outer cylindrical portion. The inner cylindrical portion and the outer cylindrical portion having a large coefficient of thermal expansion may press a cylindrical portion of the thermal anchor having a small coefficient of thermal expansion. Accordingly, such a coupling structure may inhibit cold leak caused by a difference in coefficients of thermal expansion.

In addition, reinforcement plates are installed above and below an external washer portion of the thermal anchor, respectively. The reinforcement plate may increase a contact area, improve mechanical stability, and improve sealing characteristics. The cylindrical portion of the thermal anchor may be disposed between double walls of the neck portion. The cylindrical portion of the thermal anchor may be screwed to an external side surface of the inner cylindrical portion of the inner container to provide sealing. A cylindrical portion of the reinforcement plate may be screwed to an internal side surface of the outer cylindrical portion to provide sealing. In addition, an internal side surface of the cylindrical portion of the reinforcement plate may be screwed to the external side surface of the cylindrical portion of the thermal anchor to provide sealing. A neck structure divided into an upper portion and a lower portion may reduce mechanical stability, but the reinforcement plate may improve mechanical stability while improving sealing characteristics of the divided neck structure.

A reinforcement plate may be used to maintain a constant gap between the inner cylindrical portion and the outer cylindrical portion in the neck portion having the double-wall structure. Reinforcement plates may be disposed at the top and bottom of the neck portion, respectively. The reinforcement plate may have a flange bushing structure.

The refrigerant storage device according to an example embodiment may prevent introduction of radiant heat by installing a superinsulator SI between the inner cylindrical portion and the outer cylindrical portion constituting the neck portion of the internal container. A getter may be provided between the inner cylindrical portion and the outer cylindrical portion. The getter may be charcoal. The getter may induce a natural vacuum formed by cooling the internal container, and the natural vacuum may block the introduction of convective heat.

In the refrigerant storage device according to an example embodiment, naturally vaporized refrigerant gas may flow only through a hole or groove formed in an inner washer portion of the thermal anchor protruding inwardly of the neck portion of the inner container. Accordingly, refrigerant vaporization gas and the thermal anchor may perform sufficient heat exchange, and a cooling temperature and a cooling rate of the thermal anchor may be significantly improved. Accordingly, utilization of waste heat may increase.

In the refrigerant storage device according to an example embodiment, a temperature control rod formed of a metal having high thermal conductivity may be installed inside the inner container in thermal contact with the thermal anchor. The temperature control rod may be brought into thermal contact with the refrigerant vaporization gas to be cooled. The number and length of temperature control rods may adjust the temperature of the thermal anchor and the evaporation rate of the refrigerant to meet user's requests. An insertion depth of the temperature control metal rod may be adjusted to control the temperatures of the thermal anchor and SQUID sensor.

The refrigerant vaporization gas may be exhausted to the outside of the cooling device, and a recondenser may recondense the refrigerant vaporization gas with a liquid refrigerant and may then resupply the recondensed refrigerant vaporization gas to a cooling device.

When cooling capacity of the recondenser is higher than the refrigerant evaporation rate of the refrigerant storage container, a pressure P2 in the recondenser or a pressure P1 of the internal container may be lower than atmospheric pressure.

Refrigerant gas may not flow smoothly from the internal container to the recondenser due to negative pressure lower than atmospheric pressure. To prevent negative pressure (or a vacuum pumping effect) inside a storage container or a recondenser chamber, the recondenser may increase the pressure through forced heating to prevent the vacuum pumping effect. However, the temperature control rod may provide a pressure control (evaporation rate control) effect to remove the forced heating of the recondenser. In addition, the temperature control rod may be thermally coupled to the thermal anchor to stably cool the thermal shield and the SQUID sensor.

According to an example embodiment, a technology for directly recondensing refrigerant vaporization gas (or helium gas) using a refrigerator (or a condenser) and resending the recondensed refrigerant vaporization gas to a Dewar may be applied. Since the magnetic noise and vibration noise caused by the refrigerator and a refrigerant delivery tube are significantly large, a special Dewar structure and a special SQUID placement method may be required to prevent a SQUID device from reacting to the vibrations.

With the recent increase in the price of helium gas, a technology for directly recondensing a helium gas using a refrigerator and resending the recondensed helium to a Dewar is required. Vaporized helium is supplied to a refrigerator through a refrigerant exhaust tube, and a liquefied refrigerant is supplied to the Dewar through a refrigerant injection tube. When the refrigerant exhaust tube and the refrigerant injection tube constitute a single pipe, a refrigerant inside the pipe fails to be maintained in a cold state due to heat exchange between the inside and the outside of the pipe.

A coil-in-vacuum (CIV) SQUID according to an example embodiment addresses an issue regarding ice condensation on a baffle insert lid using a coaxial double-tube structure. Each of an exhaust tube of refrigerant-vaporized gas and a refrigerant injection tube has a dual-tube structure. The double-tube structure may delivery cold vaporized gas to a refrigerator to increase cooling efficiency, and may control rotation and tilt posture of the Dewar.

In the CIV SQUID, the Dewar includes an internal container and an external container surrounding the internal container. However, the internal container absorbs radiant heat from the outside to increase consumption of a refrigerant.

In the CIV SQUID device according to an example embodiment, Dewar uses a double-wall structure in a neck portion of the inner container into which a baffle insert is inserted. Such a double-wall structure may significantly contribute to preventing vacuum destruction caused heat shrinkage of parts constituting an inside of the Dewar during rapid cooling. In addition, the double-wall structure may automatically form a vacuum layer when the Dewar is cooled, and the thermal shield may be disposed between double wall to reduce introduction of radiant heat from a Dewar neck. In addition, a double vacuum layer may reduce an evaporation rate of liquid helium by improving the vacuum degree of the vacuum layer through double-blocking of the fine helium gas passing through epoxy reinforced with glass fiber. In the double-wall structure, the thermal anchor may be inserted into the inner container to be in efficient thermal contact with the vaporized refrigerant. To reduce damage caused by expansion between the thermal anchor and the inner container, the thermal anchor may be inserted within the double-wall structure of the inner container and screwed to each other to reduce cold leak and improve mechanical stability. In addition, an inner washer portion of the thermal anchor, inserted into the double-wall structure, may have a plurality of holes to increase a thermal contact surface and may be in direct contact with the vaporized refrigerant to effectively use waste. Accordingly, the double-wall structure and the thermal anchor inserted between the double-wall structure may significantly maximize the effect of a heat block layer to reduce an evaporation rate of the refrigerant, and may stably support a high-load inner structure to inhibit refrigerant evaporation and noise caused by external vibration.

A magnetocardiography (MCG) device according to an example embodiment may adopt a vacuum-in-coil (CIV) SQUID facilitating maintenance of a SQUID sensor, and may include a low-temperature cooling shield structure to surround the SQUID sensor. The low-temperature cooling shield structure may be disassembled to facilitate the maintenance of the SQUID sensor.

The intensity of a magnetic signal from a magnetic field signal source decreases in inverse proportion to the square of the distance, so that a gap between the signal source and a pick-up coil needs to be significantly reduced to improve a signal-to-noise ratio. However, when the gap between the signal source and the pick-up coil is significantly narrow, the evaporation rate of the refrigerant may increase. Accordingly, there is a requirement for a device, capable of adjusting the gap between the signal source and the pick-up coil. According to the present disclosure, the gap between the signal source and the pick-up coil may be readily adjusted.

Hereinafter, example embodiments will now be described more fully with reference to the accompanying drawings, in which some example embodiments are shown. Example embodiments may, however, be embodied in many different forms and should not be construed as being limited to the embodiments set forth herein. Rather, these example embodiments are provided so that this disclosure will be thorough and complete, and will fully convey the scope of example embodiments of the present disclosure to those of ordinary skill in the art. In the drawings, the thicknesses of layers and regions are exaggerated for clarity. Like reference characters and/or numerals in the drawings denote like elements.

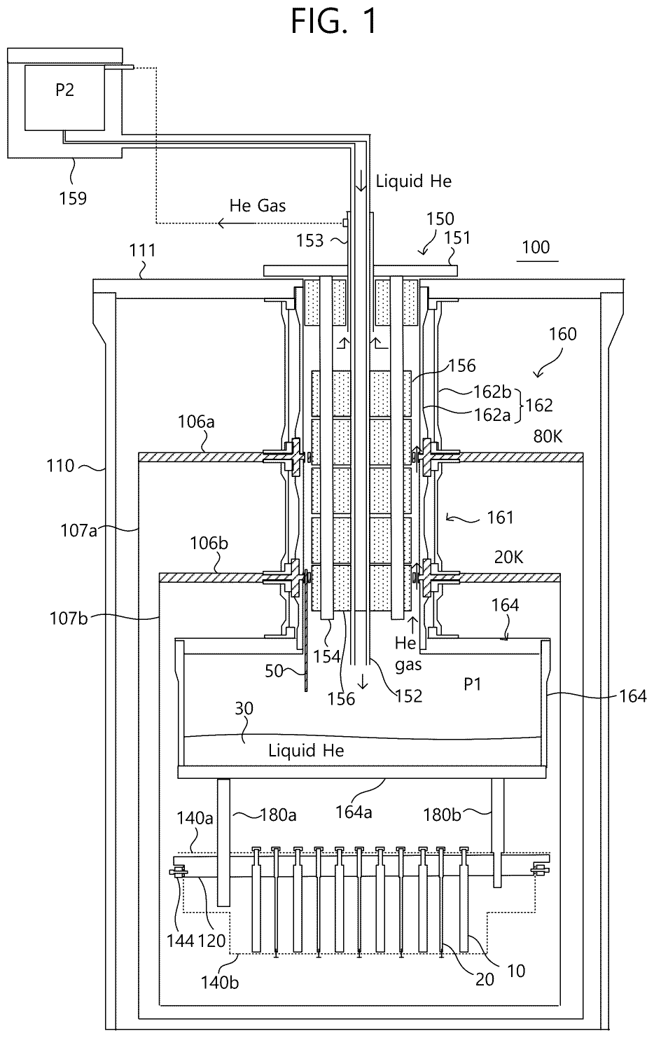

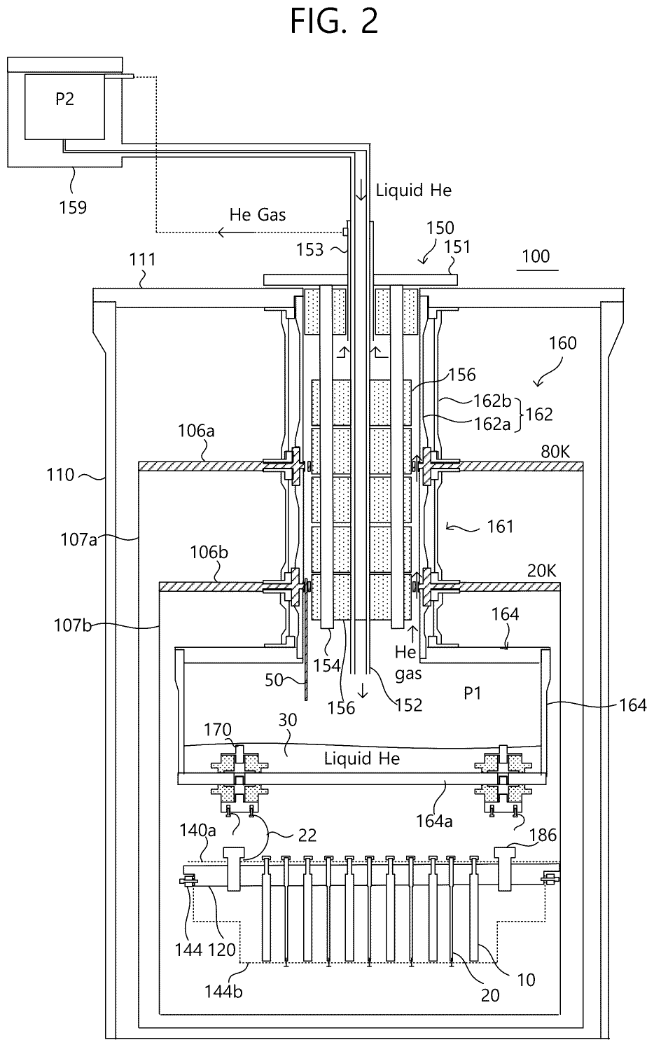

FIGS. 1 and 2 are conceptual diagrams illustrating a magnetic field measurement apparatus according to an example embodiment of the present disclosure.

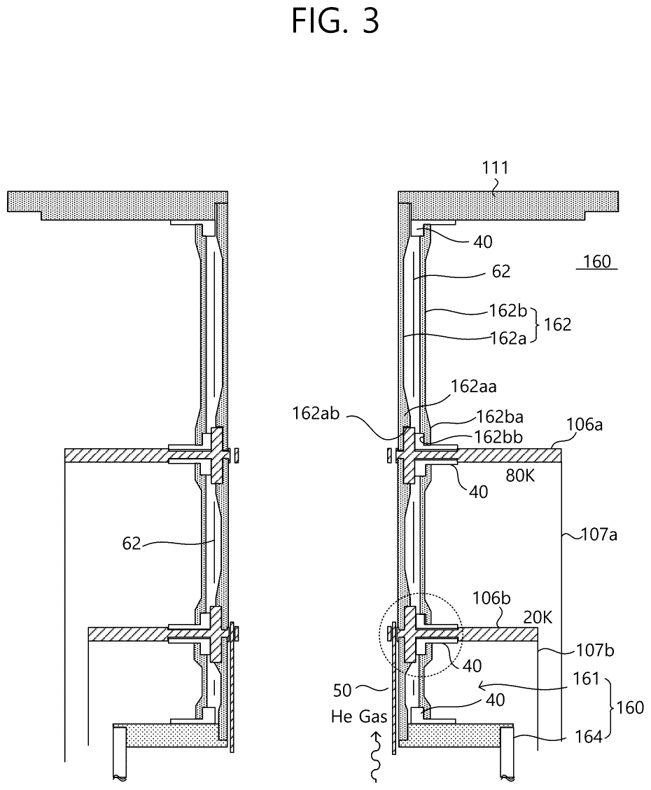

FIG. 3 is a cross-sectional view illustrating a neck portion and a thermal anchor of an inner container of the magnetic field measurement apparatus of FIG. 1.

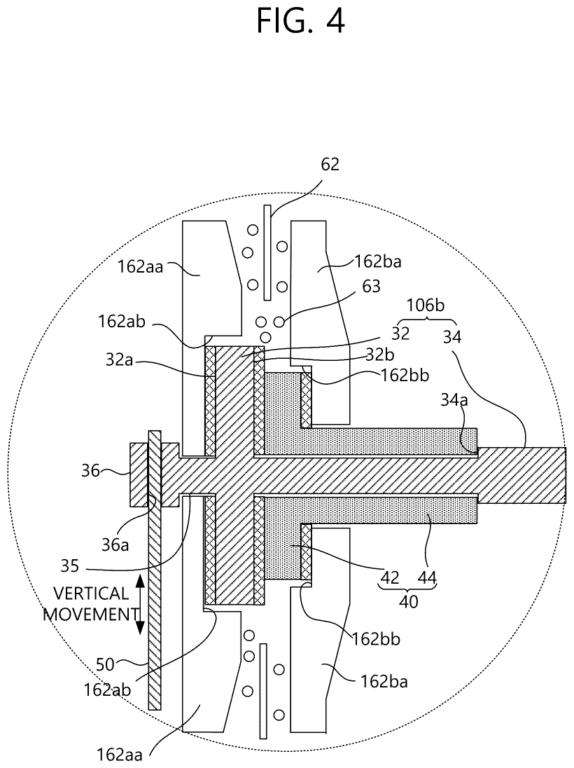

FIG. 4 is an enlarged view of a coupling portion of the thermal anchor and the neck portion of FIG. 3.

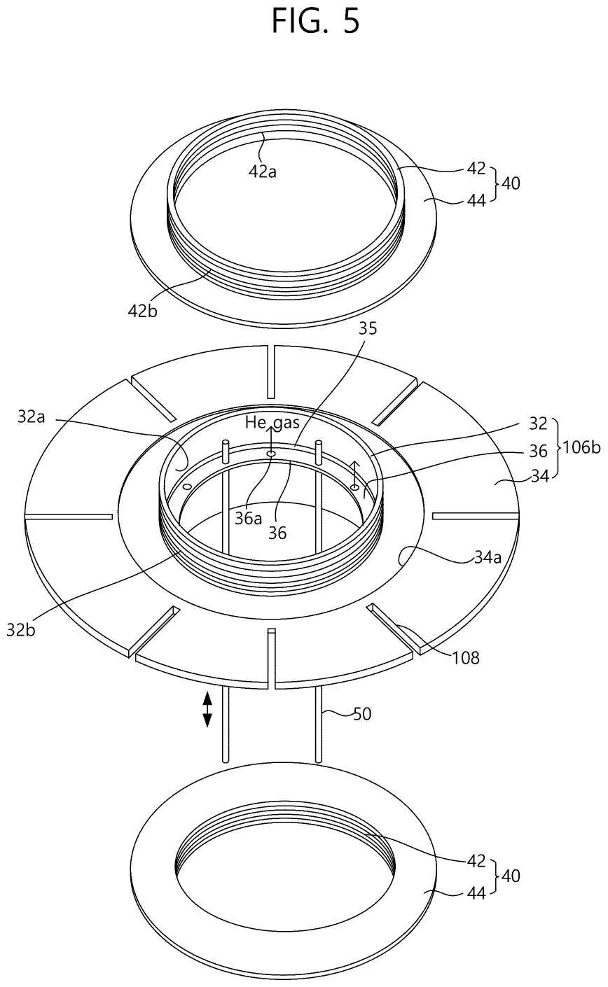

FIG. 5 is a perspective view illustrating the thermal anchor and a reinforcement plate of the magnetic field measurement apparatus of FIG. 1.

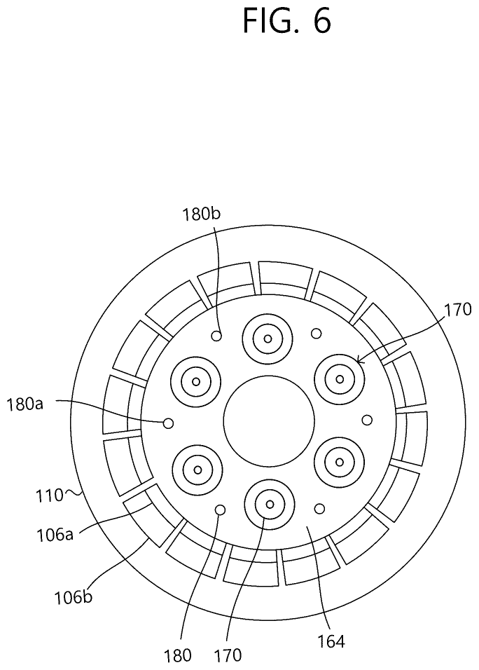

FIG. 6 is a plan view when viewing a lower surface of the inner container in the magnetic field measurement apparatus of FIG. 1.

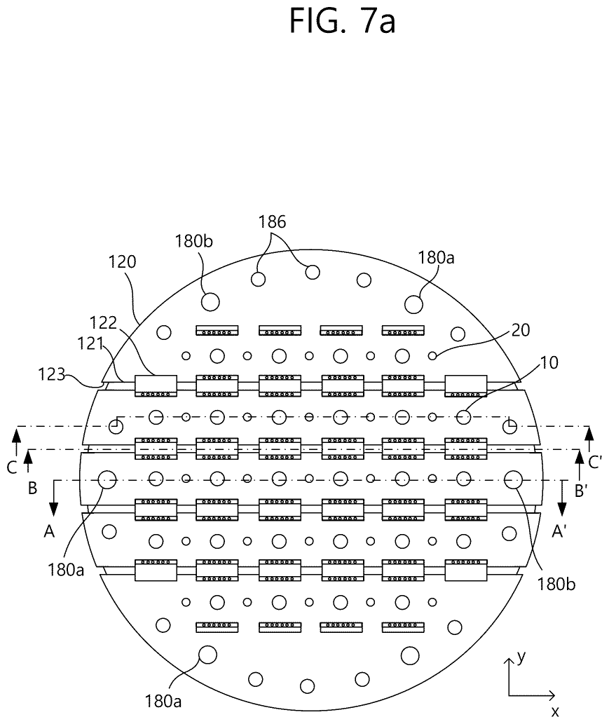

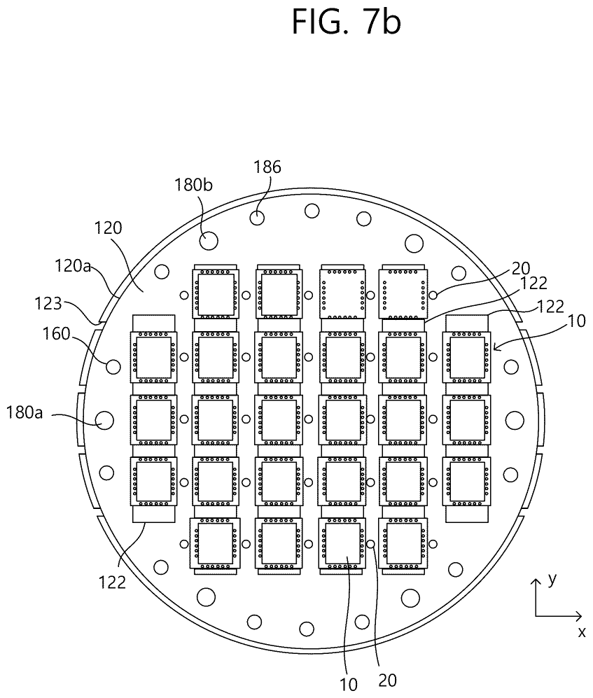

FIG. 7A is a top view of a SQUID sensor module mounting plate of the magnetic field measurement apparatus of FIG. 1.

FIG. 7B is a bottom view of the SQUID sensor module mounting plate of the magnetic field measurement apparatus of FIG. 1.

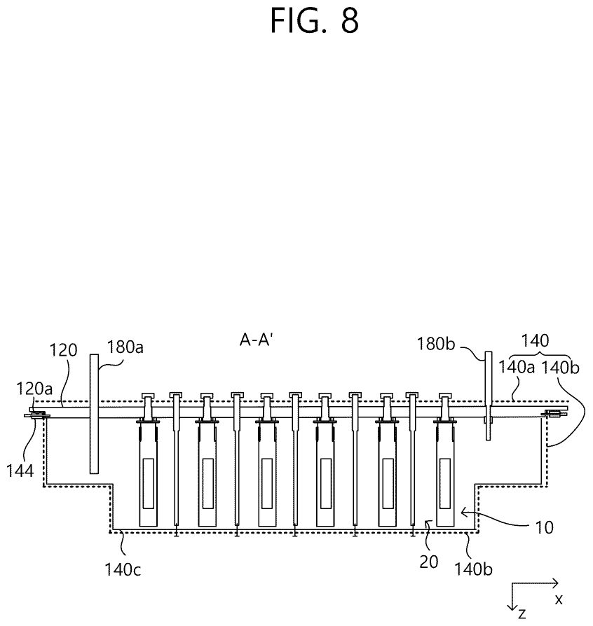

FIG. 8 is a cross-sectional view taken along line A-A′ of FIG. 7A.

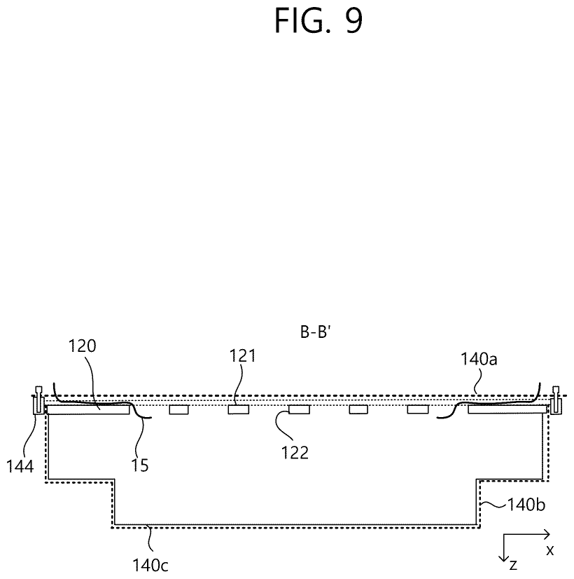

FIG. 9 is a cross-sectional view taken along line B-B′ of FIG. 7A.

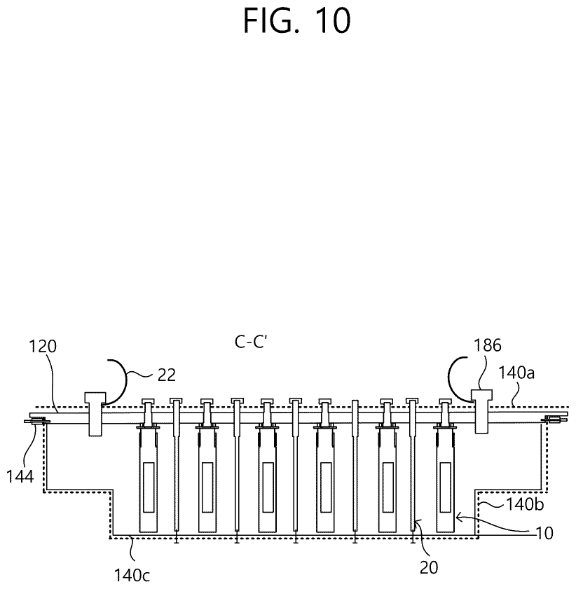

FIG. 10 is a cross-sectional view taken along line C-C′ of FIG. 7A.

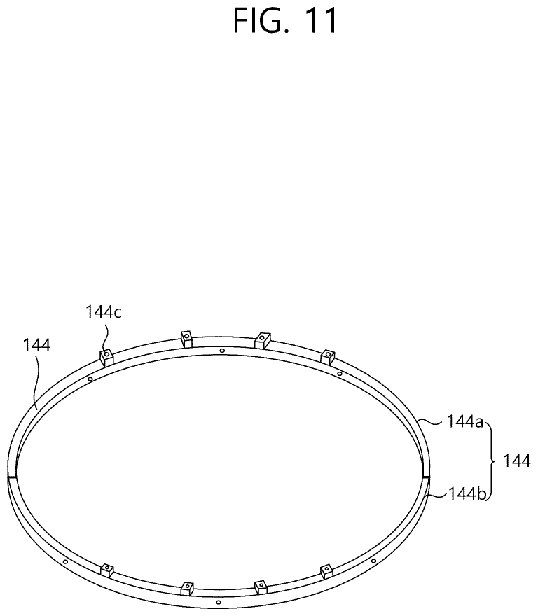

FIG. 11 is a perspective view illustrating an auxiliary thermal anchor of FIG. 1.

Referring to FIGS. 1 to 11, a cooling device 100 for a magnetic field measurement apparatus according to an example embodiment may include an outer container 110; and an inner container 160 inserted into the outer container 110 and storing a liquid refrigerant. The inner container 160 may include a neck portion 161 into which a baffle insert 150 is inserted; and a body portion 164 having a diameter increased compared to the neck portion 161. The neck portion 161 may include a plurality of cylindrical neck portions 162 vertically aligned with each other; and one or more thermal anchors 106a and 106b inserted between adjacent cylindrical neck portions 162. The thermal anchors 106a and 106b may be in direct contact with refrigerant vaporization gas. Each of the cylindrical neck portions 162 may have a double-wall structure including an inner cylindrical portion 162a and an outer cylindrical portion 162b. The thermal anchors 106a and 106b may include a cylindrical anchor portion 32 disposed between the inner cylindrical portion 162a and the outer cylindrical portion 162b; an outer washer portion 34 coupled to an external surface of the cylindrical anchor portion 32; and an inner washer portion 36 coupled to an internal surface of the cylindrical anchor portion 32.

The outer container 110 may have a cylindrical shape and may be formed of glass fiber reinforced plastic such as G10 epoxy. The outer container 110 may include an outer container top plate 111.

The inner container 160 may store liquid refrigerant 30 and may cool a SQUID sensor module 10 through a main thermal anchor 170 and a Litz wire 22. A material of the inner container 160 may be glass fiber reinforced plastic such as G10 epoxy. The interior container 160 may include a neck portion 161 into which the baffle insert 150 is inserted; a body portion 164 having a diameter increased compared to the neck portion 161. The neck portion 161 may have a double-wall structure including an inner cylindrical portion 162a and an outer cylindrical portion 162b surrounding the inner cylindrical portion 162a.

The neck portion 161 may be divided into a plurality of cylindrical neck portions 162, and thermal anchors 106a and 106b may be inserted between adjacent cylindrical neck portions 162.

A thermal shielding layer 62 may be disposed between the inner cylindrical portion 162a and the outer cylindrical portion 162b. The thermal shielding layer 62 may have a multilayer structure in which a metal thin film having high reflectivity and low emissivity and a significantly thin nonwoven fabric having low thermal conductivity are sequentially stacked. The thermal shielding layer 62 may be a superinsulator. A getter 63 may be provided between the inner cylindrical portion 162a and the outer cylindrical portion 162b. The getter 63 may be charcoal. The getter 63 may induce a natural vacuum formed by cooling the inner container, and the natural vacuum may block the introduction of convective heat.

The double-wall structure of the neck portion may block introduction of radiant heat from the outside into the inner container 160. When the inner container is cooled by a refrigerant, a space between the inner cylindrical portion 162a and the outer cylindrical portion 162b may be maintained at a natural vacuum. Accordingly, heat introduction caused by heat transfer may be blocked, and the thermal shielding layer 62 may additionally block the introduction of the radiant heat. Accordingly, the neck portion of the double-wall structure may provide higher mechanical stability and higher heat shielding efficiency than a neck portion of a single-wall structure.

An inner diameter of the inner cylindrical portion 162a may be constant, and an outer diameter of the inner cylindrical portion 162a may be large on opposite ends thereof. Opposite ends 162aa of the inner cylindrical portion 162a may have a greater thickness than other portions. One end 162aa of the inner cylindrical portion may include a first recessed portion 162ab recessed from an external side surface. The first recessed portion 162ab may be grooved for screw coupling.

An inner diameter of the outer cylindrical portion 162b may be constant, and an outer diameter of the outer cylindrical portion 162b may be large on opposite ends thereof. Opposite ends 162ba of the outer cylindrical portion may have a greater thickness than other portions. One end 162ba of the outer cylindrical portion may include a second recessed portion 162bb recessed from an internal side surface. The second recessed portion 162bb may be grooved for screw coupling.

Among the cylindrical neck portions 162, an uppermost cylindrical neck portion may be coupled to the outer container top plate 111, and a lowermost cylindrical neck portion may be coupled to the body portion 164 of the inner container 160.

The thermal anchors 106a and 106b may include a cylindrical anchor portion 32 disposed between the inner cylindrical portion 162a and the outer cylindrical portion 162b; an outer washer portion 34 coupled to an external side surface of the cylindrical anchor portion 32; and an inner washer portion 36 coupled to an internal side surface of the cylindrical anchor portion 32. The thermal anchor 106 may be integral, and may be formed of copper or aluminum having high thermal conductivity. The thermal anchors 106a and 106b may include two anchors, which may be vertically spaced apart from each other. A lower thermal anchor may be cooled to 20K, and an upper thermal anchor may be cooled to 80K.

The cylindrical anchor portion 32 may have a cylindrical shape and may include grooves 32a and 32b, respectively formed in internal and external surfaces thereof. The inner groove 32a may be screwed to a groove of the first recessed portion 162ab of the inner cylindrical portion. The outer groove 32b may be screwed to an inner surface groove 42a of a reinforced cylindrical portion 42.

The outer washer portion 34 may have a washer shape and may be coupled to a center of the external side surface of the cylindrical anchor portion. The inner washer portion 36 may have a washer shape and may be coupled to a center of the internal side surface of the cylindrical anchor portion.

An upper portion and a lower portion of the cylindrical anchor portion 32 may be inserted between the inner cylindrical portion and the outer cylindrical portion to be screwed to each other.

The inner washer portion 36 may include a plurality of refrigerant through-holes 36a arranged in an azimuth direction. The refrigerant vaporization gas may move through the refrigerant through-holes 36a.

A temperature control rod 50 may be coupled to at least one of the refrigerant through-holes 36a, and may extend in a direction in which the inner container extends. The temperature control rod 50 may be cooled through heat exchange with the refrigerant vaporization gas, and may cool the thermal anchor 106b to 20K, a temperature of the refrigerant vaporization gas. The temperature control rod 50 may have one end having a screw structure, and may be coupled to the cooling refrigerant through-hole to adjust a length thereof.

The temperature control rod 50 may control temperatures of a 20K thermal shielding layer 107b and the thermal anchor 106a, surrounding the SQUID sensor module, to effectively cool the SQUID sensor.

Due to excessive liquefaction of helium in a recondenser 159, negative pressure may be generated inside a Dewar and inside a recondensation chamber. When negative pressure is generated, open air may be introduced into the recondenser chamber and the Dewar, and icing may occur on a surface of a cold head of the recondenser 159. When the icing occurs continuously, the efficiency of the recondenser 159 may be rapidly reduced to prevent the recondenser 159 from liquefying helium gas. When an internal pressure P1 of the Dewar and a pressure P2 of the recondenser 159 decreases to a predetermined range (0.2 pounds per square inch (PSI) to 0.5 PSI) or less to prevent the icing of the cold head, a heater attached to the cold head may apply power of about 0.5 watt (W) to continuously perform forced heating. The continuous application of power to heaters may cause loss of energy and equipment. The temperature control rod 50 may control pressures of the Dewar and the recondenser chambers by increasing a helium evaporation rate to prevent icing of the cold head caused by the negative pressure.

Accordingly, the temperature control rod 50 may simultaneously improve cooling efficiency of the SQUID sensor and control the helium evaporation rate by adjusting a vertical height thereof.

A reinforcement portion 40 may include a cylindrical reinforcement portion 42 and a washer-shaped reinforcement flange portion 44 coupled to an external side of one end of the cylindrical reinforcement portion. The reinforcement portion 40 may be formed of glass fiber reinforced plastic such as G10 epoxy. The reinforcement portion 40 may be screwed to the cylindrical anchor portion 32 and screwed to the outer cylindrical portion to provide sealing and mechanical stability. In addition, the cylindrical anchor portion 32 may be screwed to the inner cylindrical portion and the reinforcement portion 40 to provide sealing and mechanical stability.

An internal side surface of the cylindrical reinforcement portion 42 may include an inner groove 42a for screw connection to a groove 32a of an external side surface of the cylindrical anchor portion 32. An external side surface of the cylindrical reinforcement 42 may include an outer groove 42b for screw connection to a groove of a second recessed portion 162bb of the cylindrical outer portion 162b.

The cylindrical reinforcement portion 42 may be inserted into and coupled to the second recessed portion 162bb of the outer cylindrical portion 162b. The outer groove 42b on the external side surface of the cylindrical reinforcement portion 42 may be screwed to a groove formed in the second recessed portion 162bb . The inner groove 42a on the internal side surface of the cylindrical reinforcement portion may be screwed to an outer groove 32b formed on the external side surface of the cylindrical anchor portion 32.

The outer washer portion 34 may include a first step portion 34a coupled to the reinforcement flange portion 44. The first step portion 34a may have a ring-shaped recessed structure. The first step portion 34a may be formed on an upper surface and a lower surface of the outer washer portion 34, respectively.

The inner washer portion 36 may include a second step portion 35 coupled to one end of the inner cylindrical portion 162a. The second step portion 35 may have a ring-shaped recessed structure. The second step portion 35 may be formed on an upper surface and a lower surface of the inner washer portion 36, respectively.

The thermal anchors 106a and 106b may be inserted into the neck portion and arranged sequentially to be vertically spaced from each other. An outer diameter of the overlying first thermal anchor 106a may be larger than an outer diameter of the underlying second column anchor 106b. Each of the thermal anchors 106a and 106b may include a plurality of slits 108 extending in a radial direction.

The first thermal anchor 106a may be connected to an 80K thermal shielding layer 107a, and the second thermal anchor 106b may be connected to a 20K thermal shielding layer 107b. The 20K thermal shielding layer 107b may be disposed to surround a 4K thermal shielding portion 140.

A space between the inner container 160 and the outer container 110 may be maintained in a vacuum state. An outer container lid 111 may include an exhaust port connected to a vacuum pump. The exhaust port may be formed from a G-10 epoxy tube. A lower surface 164a of the body portion 164 may include a plurality of getter grooves. A getter, collecting residual gas in the vacuum state, may be disposed in the getter groove.

The baffle insert 150 may be disposed to be inserted into the neck portion 161 of the inner container 160. The baffle insert 150 may include an insert top plate 151, a baffle 156 disposed below the insert top plate 151, and a plurality of guide rods 154 supporting the baffle 156 and fixed to the insert top plate 151.

The insert top plate 151 may have a disk shape and may be formed of G-10 epoxy. The insert top plate 151 may be fixed to the outer container lid 111. The guide rod 154 may be formed of G-10 epoxy and may have a rod shape or a pipe shape. The guide rod 154 may support the baffle 156. The baffle 156 may include an expanded polystyrene having high thermal insulation properties and a conductive plate. The conductive plate may include an aluminum-coated mylar and a copper layer sequentially stacked to block radiant heat.

The refrigerant exhaust tube 153 may be disposed on the insert top plate 151 of the baffle insert 150, and may exhaust the vaporized refrigerant. A refrigerant injection tube 152 may be disposed on the insert top plate 151 of the baffle insert 150, and may inject a refrigerant. Each of the refrigerant exhaust tube 153 and the refrigerant injection tube 152 may have a double-tube structure including an inner tube and an outer tube. In the double-tube structure, a space between the inner tube and the outer tube may be maintained in a vacuum state during cooling. The refrigerant injection tube 152 may have a coaxial structure inserted into the refrigerant exhaust tube 153. The refrigerant exhaust tube 153 and the refrigerant injection tube 152 may be formed of G-10 epoxy.

The coaxial double tubes 152 and 153 may reduce thermal contact with the insert top plate 151 to reduce formation of ice on the insert top plate 151. When each of the refrigerant exhaust tube and the refrigerant injection tube have a single-tube structure, the insert top plate 151 and the refrigerant exhaust tube form ice. The ice may impede sealing of the outer container lid 111 and the insert top plate 151, and may increase introduction of external heat. The coaxial double tubes 152 and 153 may be disposed on a central axis of the insert top plate 151. One end of the refrigerant exhaust tube 153 may be disposed in a higher location than the first thermal anchor 106a.

The recondenser 159 may be connected to the refrigerant exhaust tube 153 and the refrigerant injection tube 152, and may recondense the vaporized refrigerant exhausted through the refrigerant injection tube 153. The recondenser 159 may be disposed outside a magnetically shielded room.

A signal line connection box may be disposed outside the outer container, and may connect signal lines 15 of the SQUID sensor.

Main thermal anchors 170 may be cooled by the refrigerant, and may be arranged at regular intervals on a constant circumference on the lower surface of the inner container 160. The main thermal anchors 170 may include six main thermal anchors 170.

The main thermal anchor 170 may cool the 4K thermal shielding portion 140 and the SQUID sensor modules 10 through the Litz wire 22.

Returning to FIG. 1, a sensor guide rod 180a may be mounted on the lower surface 164a of the inner container and extend through the SQUID sensor module mounting plate 120, and may guide vertical movement of the SQUID sensor module mounting plate 120. The sensor guide rod 180a may be periodically disposed on a circumference having a constant radius on the lower surface 164a of the inner container.

A sensor fixing rod 180b may be mounted on the lower surface 164a of the inner container, and may be fixed to the SQUID sensor module mounting plate 120. The sensor fixing rod 180b may be periodically disposed on a circumference having a constant radius on the lower surface 164a of the inner container. A length or a fixed location of the sensor fixing rod 180b may be adjusted to adjust a distance between the magnetic field signal source and the pick-up coil.

The SQUID sensor module mounting plate 120 may have a disk shape and may be formed of a non-magnetic material such as G10 epoxy. The SQUID sensor module mounting plate 120 may include a ring-shaped ring recessed portion 120a on a lower surface of a side surface thereof. The SQUID sensor module mounting plate 120 may include at least one connection portion 123 penetrating through the SQUID sensor module mounting plate 120 in the ring recessed portion 120a.

The SQUID sensor modules 10 may penetrate through the SQUID sensor module mounting plate 120, and may be arranged in a first direction (an X-axis direction) and a second direction (a Y-axis direction). Each of the SQUID sensor modules 10 may extend vertically. For example, the SQUID sensor modules 10 may be arranged in a matrix in the first and second directions. An upper surface of the SQUID sensor module mounting plate 120 may include a trench 121 spaced apart from the SQUID sensor modules, arranged in the first direction, in the second direction to extend from the SQUID sensor module mounting plate 120 in the first direction between the SQUID sensor modules arranged in the first direction. Signal line connection holes 122 may be connected to the trench 121 and arranged at regular intervals in the first direction, and may penetrate through the SQUID sensor module mounting plate 120. The signal line connection hole 122 and the trench 121 may provide a connection path for signal lines of a plurality of SQUID sensors constituting the SQUID sensor module.

The auxiliary thermal anchor 144 may include at least one projection 144c coupled to the ring recessed portion 120a and protruding to be inserted into the thermal connection portion 123, and the trench 121 disposed on an outermost side in the first direction may be connected to the connection portion 123.

The auxiliary thermal anchor 144 may be coupled to a side surface of the SQUID sensor module mounting plate 120 with the 4K thermal shielding portion 140 interposed therebetween, and may have a ring shape fixing the 4K thermal shield 140. The auxiliary thermal anchor 144 may be in thermal contact with the 4K thermal shielding portion 140 to cool the 4K thermal shielding portion 140. The auxiliary thermal anchor 144 may be formed of acid-free copper, and may be divided into a first auxiliary thermal anchor 150a and a second auxiliary thermal anchor 150b having a semicircular shape to inhibit eddy current from flowing.

The 4K thermal shielding portion 140 may include an upper 4K thermal shielding portion 140a disposed on the upper surface of the SQUID sensor module mounting plate 120; and a lower 4K thermal shielding portion 140b disposed to surround the plurality of SQUID sensor modules. The auxiliary thermal anchor 144 may be coupled to the side surface of the SQUID sensor module mounting plate through the lower 4K thermal shielding portion 140b. The lower 4K thermal shielding portion 140b may be disposed to surround the 4K thermal shielding housing 140c. The 4K thermal shielding housing 140c may be formed of a thin plastic material. The 4K thermal shielding housing 140c may have at least one opening for vacuum exhaustion. The 4K thermal shielding housing 140c may have a raised spot extending in a vertical direction to have a small diameter, in a region in which the SQUID sensor modules 10 are disposed, to reduce a cooling space.

A plurality of heat transfer fixing portions 186 may be periodically mounted along an edge of the SQUID sensor module mounting plate 120. The heat transfer fixing portions 186 may be formed of a metal such as acid-free copper having a high heat transfer rate. The plurality of heat transfer fixing portions 186 may be in thermal contact with the main thermal anchor 170 through a Litz wire 22 and may cool the 4K thermal shielding portion 140a while fixing the 4K thermal shielding portion 140a, and may be fixed to the plurality of heat transfer fixing portions 186 through the Litz wire 22. The Litz wire 22 may include a plurality of flexible copper wires.

A plurality of heat transfer rods 20 may be fixed to the SQUID sensor module mounting plate 120, and may extend parallel to the SQUID sensor modules 10. The plurality of heat transfer rods 20 may be arranged in a matrix form. The heat transfer rods 20 may penetrate through the SQUID sensor module mounting plate 120, and may have opposite ends, each connected to and fixed to the 4K thermal shielding portion 140 to be in thermal contact therewith.

Each of the plurality of SQUID sensor modules 10 may be cooled by the 4K thermal shielding portion 140. The space between the outer container 110 and the inner container 160 may be in a vacuum state. The magnetic field measurement apparatus 100 may measure electrocardiogram (ECG), and may be disposed inside a magnetically shielded room.

When a portion of the SQUID sensor modules 10 malfunctions, the SQUID sensor modules 10 may be divided and replaced. To this end, the auxiliary thermal anchor 144 may be removed from the SQUID sensor module mounting plate 120, and the 4K thermal shield 140 may then be removed. Accordingly, the SQUID sensor module which has malfunctioned may be readily replaced.

Although the present disclosure and its advantages have been described in detail, it should be understood that various changes, substitutions and alterations can be made herein without departing from the spirit and scope of the disclosure as defined by the following claims.

1. A refrigerant storage device for a magnetic field measurement apparatus, the refrigerant storage device comprising:
an outer container; and
an inner container inserted into the outer container and storing a liquid refrigerant,
wherein
the inner container comprises:
a neck portion into which a baffle insert is inserted; and
a body portion having a diameter increased compared to the neck portion, the neck portion comprises:
a plurality of cylindrical neck portions aligned vertically with each other; and
at least one thermal anchor inserted between cylindrical neck portions adjacent to each other,
the thermal anchor is in direct contact with refrigerant vaporization gas,
each of the cylindrical neck portions has a double-wall structure comprising an inner cylindrical portion and an outer cylindrical portion, and
the thermal anchor comprises:
a cylindrical anchor portion disposed between the inner cylindrical portion and the outer cylindrical portion;
an outer washer portion coupled to an external side surface of the cylindrical anchor portion; and
an inner washer portion coupled to an internal side surface of the cylindrical anchor portion.

2. The refrigerant storage device as set forth in claim 1, wherein
the inner washer portion comprises a plurality of refrigerant through-holes arranged in an azimuth direction, and
the refrigerant vaporization gas moves through the refrigerant through-holes.

3. The refrigerant storage device as set forth in claim 2, further comprising:
a temperature control rod coupled to the refrigerant through-hole to extend in a direction in which the inner container extends.

4. The refrigerant storage device as set forth in claim 1, wherein
one end of the inner cylindrical portion comprises a first recessed portion recessed on an external side surface, and
the cylindrical anchor portion is coupled to the first recessed portion.

5. The refrigerant storage device as set forth in claim 4, wherein
a reinforcement portion comprises a cylindrical reinforcement portion and a washer-shaped reinforcement flange portion coupled to an external side of one end of the cylindrical reinforcement portion,
one end of the outer cylindrical portion comprises a second recessed portion recessed on an internal side surface, and
the cylindrical reinforcement portion is inserted into and coupled to the second recessed portion of the outer cylindrical portion.

6. The refrigerant storage device as set forth in claim 5, wherein
the outer washer portion further comprises a first step portion coupled to the reinforcement flange portion.

7. The refrigerant storage device as set forth in claim 1, wherein
the inner washer portion further comprises a second step portion coupled to the inner cylindrical portion.

8. The refrigerant storage device as set forth in claim 1, wherein
an inner diameter of the inner cylindrical portion is constant,
an outer diameter of the inner cylindrical portion is larger on opposite ends of the inner cylindrical portion,
an inner diameter of the outer cylindrical portion is constant, and
an outer diameter of the outer cylindrical portion is larger on opposite ends of the outer cylindrical portion.

9. The refrigerant storage device as set forth in claim 1, further comprising:
a refrigerant exhaust tube disposed at the baffle insert and exhausting vaporized refrigerant gas;
a refrigerant injection tube disposed at the baffle insert and injecting a refrigerant; and
a recondenser connected to the refrigerant exhaust tube and the refrigerant injection tube and condensing a vaporized refrigerant exhausted through the refrigerant injection tube,
wherein
the refrigerant exhaust tube and the refrigerant injection tube have a coaxial structure.

10. The refrigerant storage device as set forth in claim 9, wherein
the refrigerant injection tube has a double-tube structure comprising an inner tube and an outer tube.

11. A refrigerant storage device for a magnetic field measurement apparatus, the refrigerant storage device comprising:
an outer container; and
an inner container inserted into the outer container and storing a liquid refrigerant,
wherein
the inner container comprises:
a neck portion into which a baffle insert is inserted; and
a body portion having a diameter increased compared to the neck portion,
the neck portion comprises:
a plurality of cylindrical neck portions aligned vertically with each other; and
at least one thermal anchor inserted between cylindrical neck portions adjacent to each other,
the thermal anchor is in direct contact with a refrigerant vaporization gas, and
a temperature control rod is coupled to the thermal anchor to extend within the inner container in a direction in which the inner container extends.

12. The refrigerant storage device as set forth in claim 11, wherein
each of the cylindrical neck portions has a double-wall structure comprising an inner cylindrical portion and an outer cylindrical portion, and
the thermal anchor comprises:
a cylindrical anchor portion disposed between the inner cylindrical portion and the outer cylindrical portion;
an outer washer portion coupled to an external side surface of the cylindrical anchor portion; and
an inner washer portion coupled to an internal side surface of the cylindrical anchor portion.

13. The refrigerant storage device as set forth in claim 12, wherein
the inner washer portion comprises a plurality of refrigerant through-holes arranged in an azimuth direction, and
the refrigerant vaporization gas moves through the refrigerant through-holes.

14. The refrigerant storage device as set forth in claim 12, wherein
the temperature control rod is coupled to the refrigerant through-hole.
